(19) United States
(12) Patent Application Publication
(10) Pub. No.: US 2005/0042851 A1
(43) Pub. Date: Feb. 24, 2005

(54) Connector terminal device and its fabrication method

(75) Inventor: Huan-Li Wen, Taoyuan Hsien (TW)

Correspondence Address: BACON & THOMAS, PLLC, 625 SLATERS LANE, FOURTH FLOOR, ALEXANDRIA, VA, 22314, US

(73) Assignee: SPEED TECH CORP., Taoyuan Hsien (TW)

(21) Appl. No.: 10/642,637

(22) Filed: Aug. 19, 2003

(51) Int. Cl. H01L 21/44; H01L 21/48; H01L 21/50; H05K 3/20; H05K 3/30

(52) U.S. Cl. 438/611; 438/117; 438/125; 29/831; 29/834

(57) ABSTRACT

A connector terminal device fabrication method in which a substrate is drilled to form through holes, a copper foil is overlaid on the substrate, and then the copper foil is etched, forming contact spring arms in the holes for the contact of the electronic contacts of electronic members and circuit lines respectively extended from the contact spring arms.

### BACKGROUND OF THE INVENTION

1. Field of the Invention

The present invention relates to the fabrication of connector terminal devices and, more specifically to such a connector terminal device fabrication method, which forms contact spring arms and connected circuit lines in a substrate by drilling through holes in the substrate and then overlaying a copper foil on the substrate and then etching the copper foil.

2. Description of the Related Art

Following fast development of computer network technology, communication among people at different places becomes easy and convenient. Using a computer, one can gain practical knowledge through the Internet. Modern computers are made lighter, thinner, shorter and smaller than ever. In order to save space, computer component parts are also made as smaller as possible. FIG. 12 is a sectional side view of a computer connector for LGA (Land Grid Array) connection of electronic components or circuit boards. As illustrated, the circuit board A has through holes A1, and terminals B are installed in the through holes A1 of the circuit board A. Each terminal B has a base B1 and two spring arms B2 respectively extended from the base B1 and terminating in a respective contact portion B21 for the contact of one electric contact C1 of an electronic component C. The fabrication of this design of computer connector is complicated because the circuit board A and the terminals B must be separately made.

### SUMMARY OF THE INVENTION

The present invention has been accomplished under the circumstances in view. It is the main object of the present invention to provide a connector terminal device fabrication method, which greatly simplifies the fabrication of connector terminal devices and reduces their manufacturing cost. According to one embodiment of the present invention, the connector terminal device fabrication method is to drill through holes in a substrate, and then to overlay a copper foil on the substrate, and then to etch the copper foil, forming contact spring arms in the through holes and circuit lines respectively extended from the contact spring arms. A connector terminal device made according to the present invention is comprised of a substrate and at least one copper foil. The substrate comprises a plurality of through holes. The at least one copper foil is respectively located on at least one surface of the substrate, forming a plurality of contact spring arms corresponding to the through holes and a plurality of circuit lines respectively extended from the contact spring arms for the contact of external electronic members.

### BRIEF DESCRIPTION OF THE DRAWINGS

FIG. 1 is a block diagram showing the fabrication flow of the present invention.

FIG. 2 is a schematic drawing showing holes formed in the substrate before installation of a copper foil according to the present invention.

FIG. 3 shows contact spring arms and circuit lines formed in the substrate according to the present invention.

FIG. 4 is a sectional view showing the electric contacts of an electronic member maintained in contact with the contact spring arms at the substrate.

FIG. 5 is an exploded view during the fabrication of the embodiment of the present invention.

FIG. 6 is an elevational view of the first embodiment of the present invention.

FIG. 7 is a sectional view in an enlarged scale of the first embodiment of the present invention before installation of electronic members.

FIG. 8 is similar to FIG. 7 but showing electronic members installed.

FIG. 9 is a sectional view showing an application example, of the second embodiment of the present invention.

FIG. 10 is a sectional view showing an application example of the third embodiment of the present invention.

FIG. 11 is a sectional view showing an application example of the fourth embodiment of the present invention.

FIG. 12 is a sectional side view of a computer connector according to the prior art design.

### DETAILED DESCRIPTION OF THE PREFERRED EMBODIMENT

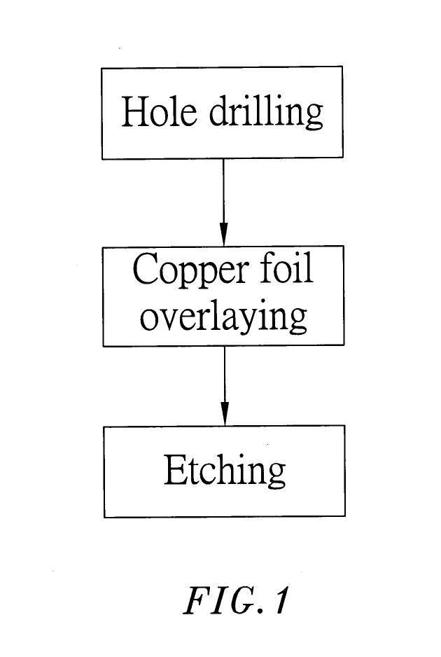

Referring to FIG. 1, a connector terminal device fabrication method in accordance with the present invention comprises the steps of (1) hole drilling, (2) copper foil overlaying, and (3) etching.

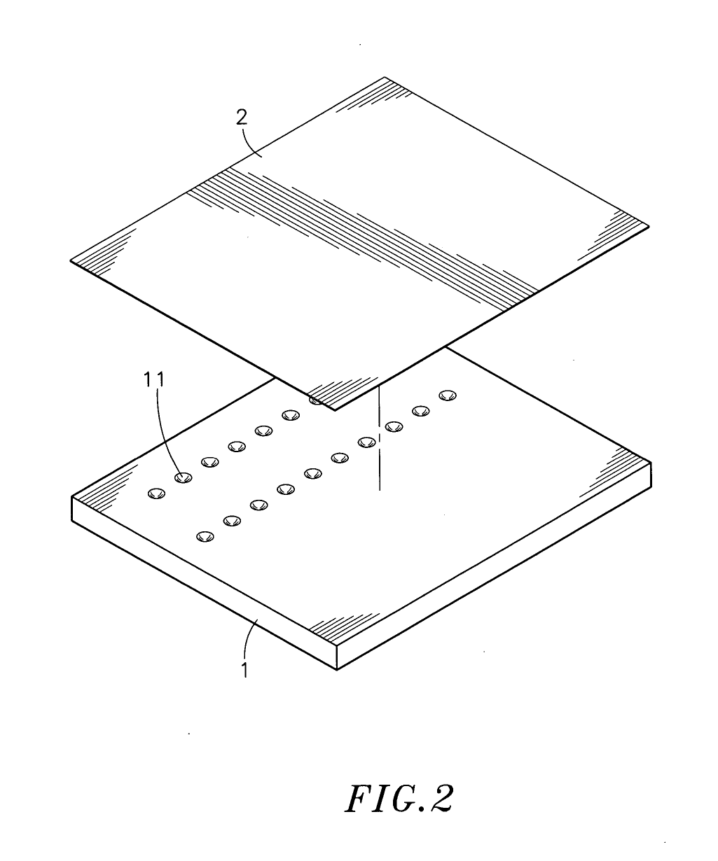

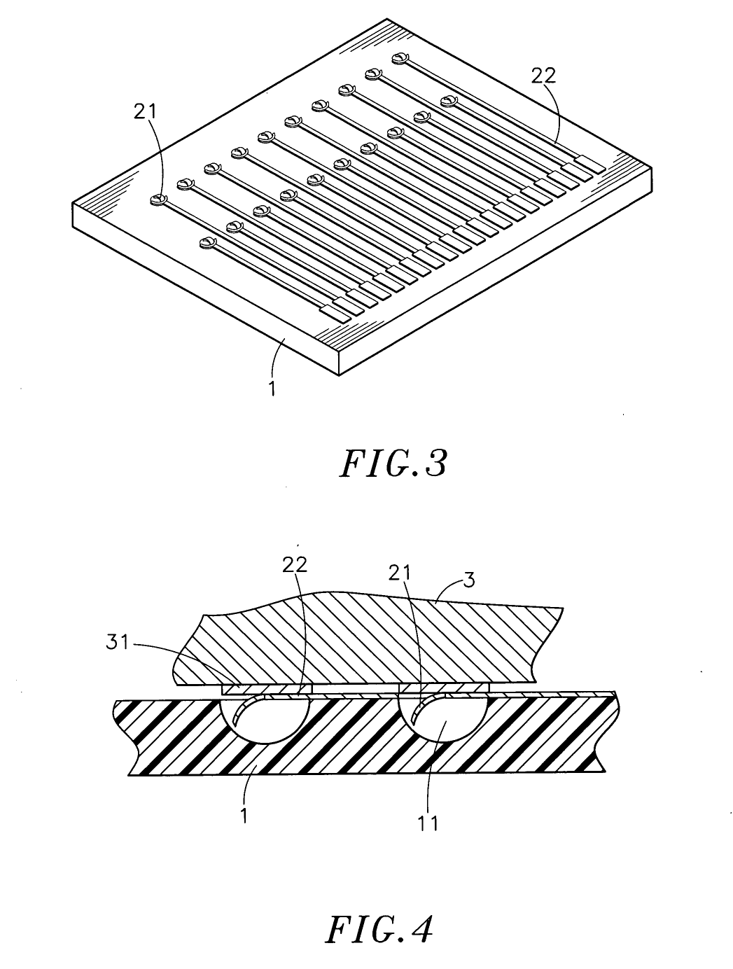

The step of (1) hole drilling is to drill through holes 11 in a substrate 1 (see FIG. 2). The step of (2) copper foil overlaying is to overlay a copper foil 2 on the whole top surface of the substrate 1 (see FIG. 2). The step of (3) etching is to etch the copper foil 2, forming contact spring arms 21 in the through holes 11 and parallel circuit lines 22 respectively extended from the contact spring arms 21 over the top surface of the substrate 1 in one direction (see FIG. 3)

Referring to FIG. 4, the electric contacts 31 of an electronic member 3 are pressed on the contact spring arms 21, causing the contact spring arms 21 to deform, and therefore the electronic member 3 is electrically connected to the corresponding circuit lines 22. The electronic member 3 can be any of a variety of electronic component parts, or a circuit board.

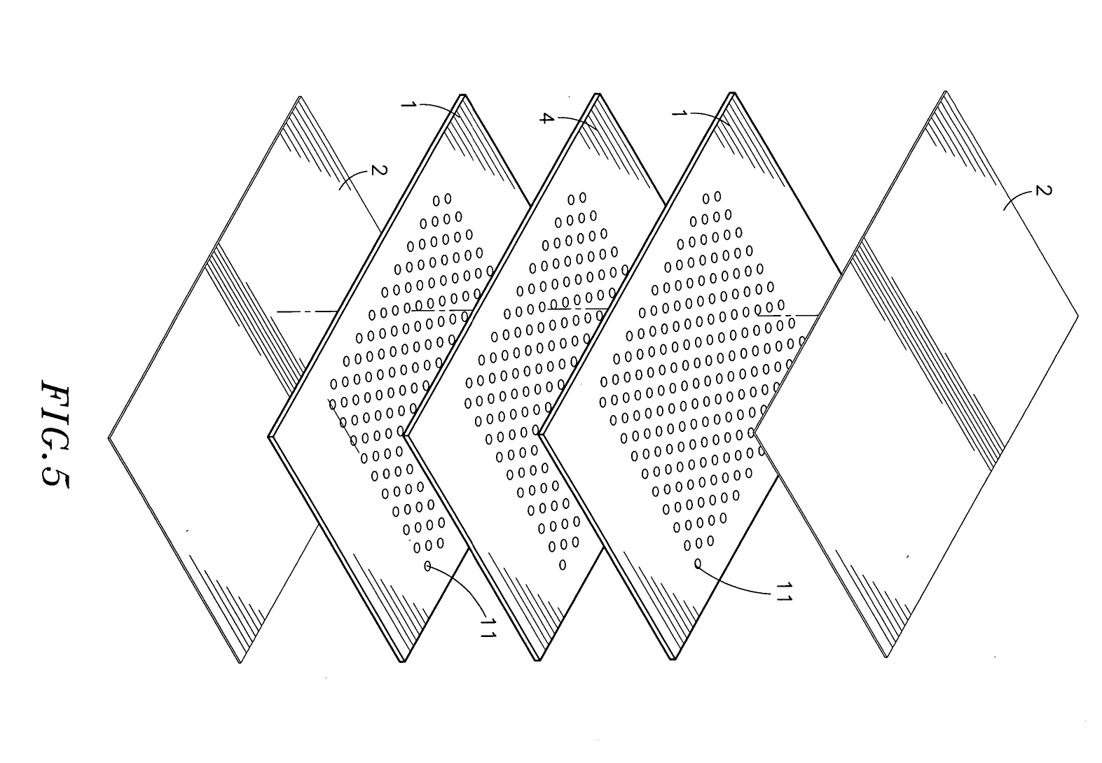

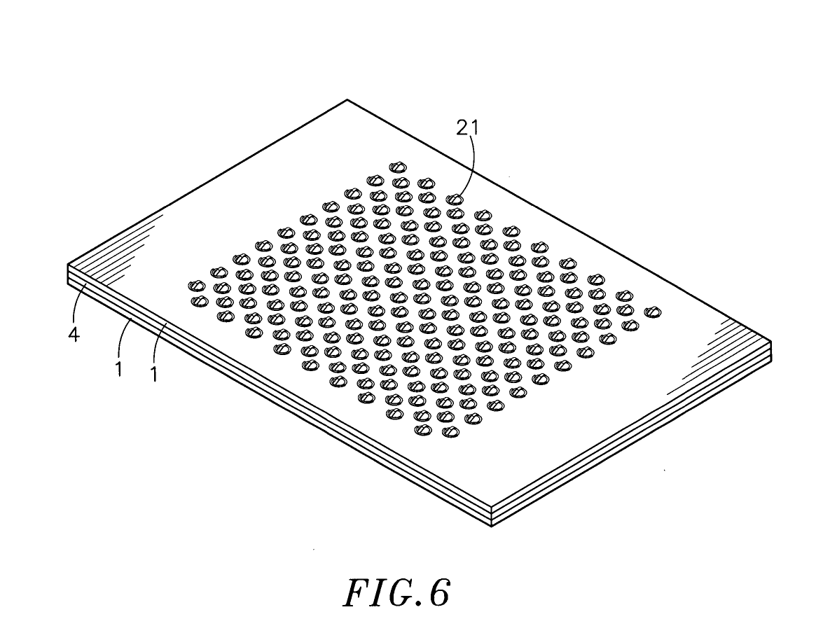

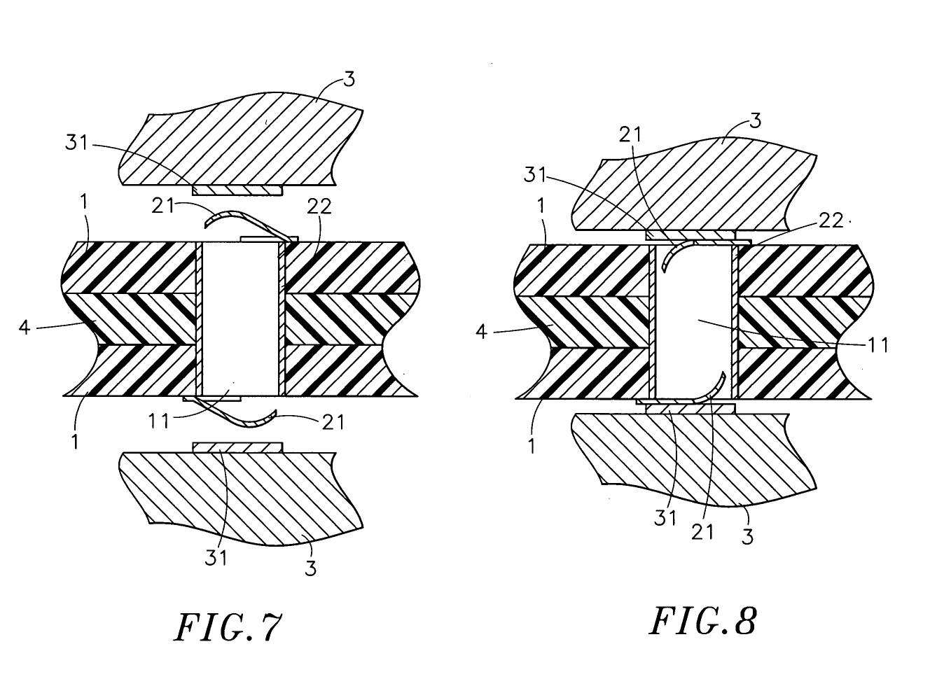

FIGS. 5˜8 are exploded view, elevational view, sectional side view in an enlarged scale before use, and sectional side view in an enlarged scale during use of the preferred embodiment of the present invention. As illustrated, an insulative layer 4 is sandwiched in between two substrates 1, through holes 11 are made through the substrates 1 and the insulative layer 4, and copper foils 2 are respectively overlaid on the surfaces of the through holes 11 and then etched, forming contact spring arms 21 and circuit lines 22 in the through holes 11. The electric contacts 31 of electronic members 3 are respectively pressed on the contact spring arms 21 at the top and bottom side of the stack of substrates 1, forming electric connection to the corresponding circuit lines 22.

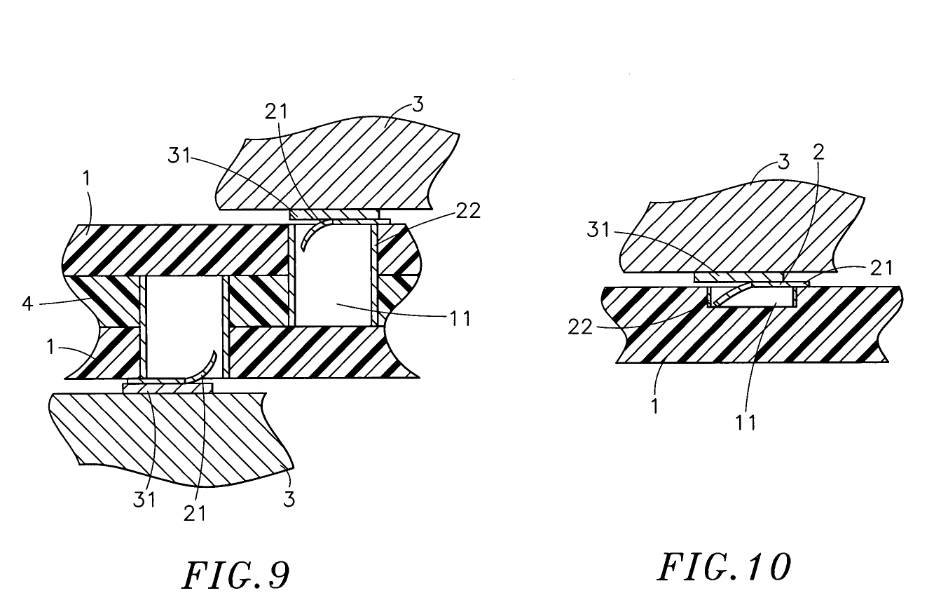

FIG. 9 shows an alternate form of the present invention. According to this embodiment, the through holes 11 in the upper and lower substrates 1 are not vertically aligned, they are arranged in staggered manner, i.e., the contact spring arms 21 and circuit lines 22 at the upper substrate and the contact spring arms 21 and circuit lines 22 at the lower substrate are separately arranged for the connection of independent electronic members 3.

FIG. 10 shows another alternate form of the present invention. According to this embodiment, the holes 11 in the substrate 1 are blind holes, which support the respective contact spring arms 21 against the pressure of the electric contacts 31 of the corresponding electronic member 3, preventing damage to the mechanical properties of the contact spring arms 21. Damage to the mechanical properties of the contact spring arms 21 cause a permanent deformation of the contact spring arms 21.

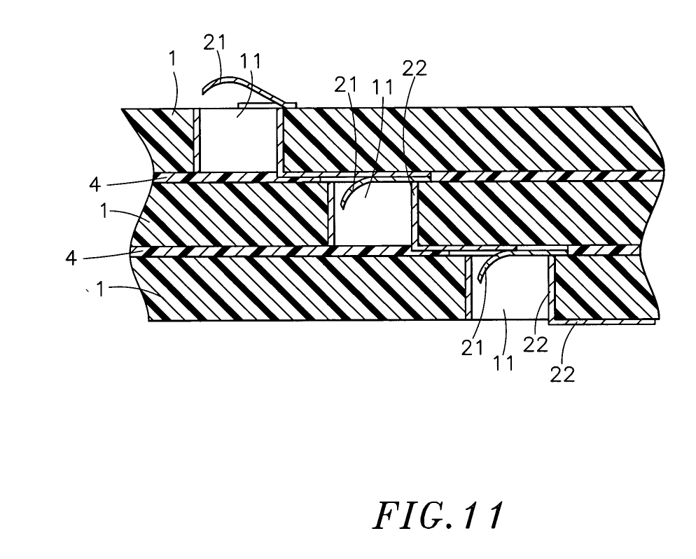

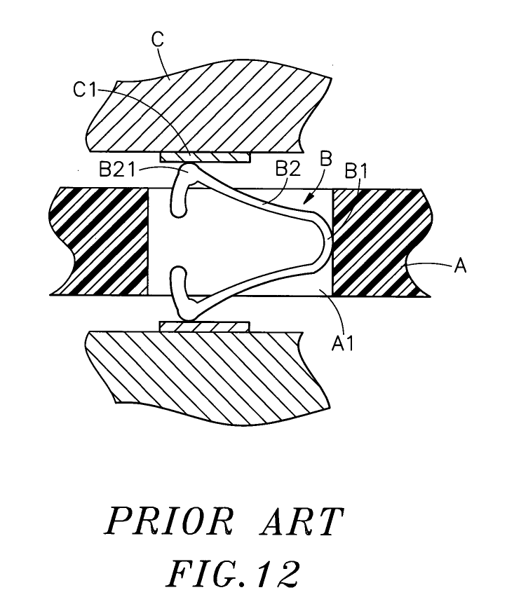

FIG. 11 shows still another alternate form of the present invention. According to this embodiment, a plurality of substrates 1 and insulative layers 4 are alternatively arranged in a stack, keeping the circuit lines 22 at one substrate 1 in electric connection to the circuit lines 22 at another substrate 1. The contact spring arms 21 and circuit lines 22 at each substrate 1 respectively extended from the respective through holes 11 to the top and bottom sides of the substrate 1. When the substrates 1 arranged with the insulative layers 4 in a stack, the circuit lines 22 at one substrate 1 are respectively set into contact with the contact spring arms 21 at another substrate 1.

A prototype of connector terminal fabrication method has been constructed with the features of FIGS. 1˜11. The connector terminal fabrication method functions smoothly to provide all of the features discussed earlier.

Although particular embodiments of the invention have been described in detail for purposes of illustration, various modifications and enhancements may be made without departing from the spirit and scope of the invention. Accordingly, the invention is not to be limited except as by the appended claims.

1. A connector terminal device fabrication method comprising the steps of:
(1) hole drilling, where a substrate is prepared and drilled, forming a plurality of holes in said substrate;
(2) copper foil overlaying, where at least one copper foil is overlaid on said substrate; and
(3) etching, where said at least one copper foil is etched, forming contact spring arms in said holes and circuit lines respectively extended from said contact spring arms.

2. The connector terminal device fabrication method as claimed in claim 1, wherein said at least one copper foil is electroplated, forming a circuit in said substrate.

3. The connector terminal device fabrication method as claimed in claim 1, wherein said contact spring arms are suspended from said substrate for the contact of electronic member means.

4. The connector terminal device fabrication method as claimed in claim 3, wherein said electronic member is a circuit board.

5. The connector terminal device fabrication method as claimed in claim 1, wherein said at least one copper foil is respectively overlaid on top and bottom surfaces of said substrate during step (2) copper foil overlaying.

6. The connector terminal device fabrication method as claimed in claim 1, wherein said holes are blind holes.

7. A connector terminal device fabrication method comprising the steps of:
(1) hole drilling, where a substrate is prepared and drilled, forming a plurality of holes in said substrate;
(2) copper foil overlaying, where copper foils are respectively overlaid on the surfaces of said holes in said substrate; and
(3) etching, where said copper foils are etched, forming contact spring arms and circuit lines respectively electrically connected in said holes.

8. The connector terminal device fabrication method as claimed in claim 7, wherein said copper foils are electroplated, forming a circuit in said substrate.

9. The connector terminal device fabrication method as claimed in claim 7, wherein said contact spring arms are suspended from said substrate for the contact of electronic member means.

10. The connector terminal device fabrication method as claimed in claim 9, wherein said electronic member is a circuit board.

11. The connector terminal device fabrication method as claimed in claim 7, wherein said copper foils are respectively partially overlaid on top and bottom surfaces of said substrate during step (2) copper foil overlaying, and etched during step (3) etching to form said contact spring arms at top and bottom sides of said substrate.

12. A connector terminal device formed of a substrate and at least one copper foil, wherein:
said substrate comprises a plurality of through holes;
said at least one copper foil is respectively located on at least one surface of said substrate, forming a plurality of contact spring arms corresponding to said through holes and a plurality of circuit lines respectively extended from said contact spring arms for the contact of at least one electronic member.

13. The connector terminal device as claimed in claim 12, wherein said circuit lines are respectively formed integral with said contact spring arms.

14. The connector terminal device as claimed in claim 12, wherein said at least one copper foil is respectively overlaid on top and bottom surfaces of said substrate.

15. The connector terminal device as claimed in claim 12, wherein said at least one copper foil is respectively overlaid on surfaces of said through holes.

16. The connector terminal device as claimed in claim 15, wherein said contact spring arms are respectively suspended in top and bottom sides of said substrate.

17. The connector terminal device as claimed in claim 12, wherein said contact spring arms and said circuit lines are adapted to accommodate a circuit board.
